(19) United States
(12) Patent Application Publication
(10) Pub. No.: US 2007/0207598 A1
(43) Pub. Date: Sep. 6, 2007

(54) Method for producing a substrate by germanium condensation

(75) Inventors: Jean-Francois Damlencourt, Saint-Egreve (FR); Remi Costa, Veynes (FR)

Correspondence Address: OLIFF & BERRIDGE, PLC, P.O. BOX 19928, ALEXANDRIA, VA, 22320, US

(73) Assignee: COMMISSARIAT A L'ENERGIE ATOMIQUE, PARIS (FR)

(21) Appl. No.: 11/707,072

(22) Filed: Feb. 16, 2007

(30) Foreign Application Priority Data
Mar. 1, 2006 (FR) 06 01850

(51) Int. Cl. H01L 21/20

(52) U.S. Cl. 438/479

(57) ABSTRACT

The method for producing a substrate comprising a silicon and germanium compound of Si_{1-Xf}Ge_{Xf} type on insulator, with Xf comprised between a first value that is not zero and 1, comprises formation of a layer of silicon and germanium of Si_{1-Xi}Ge_{Xi} type, with Xi strictly comprised between 0 and Xf, on a silicon on insulator substrate. The method then comprises a first step of thermal oxidation of the silicon of said layer at a predetermined first oxidation temperature to obtain said Si_{1-Xf}Ge_{Xf} compound by condensation of the germanium. The first thermal oxidation step comprises at least one thermal treatment step under an inert gas at said predetermined first oxidation temperature. The method can for example comprise a second thermal oxidation step performed at a predetermined second oxidation temperature, different from the predetermined first oxidation temperature.

### BACKGROUND OF THE INVENTION

The invention relates to a method for producing a substrate comprising a silicon and germanium compound of Si_{1-Xf}Ge_{Xf} type on insulator, with Xf comprised between a first value that is not zero and 1, comprising at least:
formation of a layer of silicon and germanium alloy of Si_{1-Xi}Ge_{Xi} type, with Xi strictly comprised between 0 and Xf, on a silicon on insulator substrate,
a first thermal oxidation step of the silicon of said layer at a predetermined first oxidation temperature to obtain said compound of Si_{1-Xf}Ge_{Xf} type by condensation of the germanium.

### STATE OF THE ART

The current silicon-based microelectronics technology is reaching the limits of the possibilities offered by this material. The growing need for electronic devices with better and better performances, at increasingly higher speeds and with an ever lower power consumption has led to new solutions being studied.

The microelectronics industry then turned to germanium, which is fully compatible with the technology developed for silicon and which presents the same crystalline structure as silicon, but with better properties in terms of charge carrier mobility.

A particular application concerns pMOSFETs (p-type metal-oxide-semiconductor field-effect transistors). The article “Selectively-formed high mobility SiGe-On-Insulator pMOSFETs with Ge-rich strained surface channels using local condensation technique” by T. Tezuka et al. (2004 IEEE Symposium on VLSI Technology Digest of technical papers) in particular describes fabrication of a pMOSFET the improved performances whereof can in particular be felt for charge carrier depleted transistors (FD pMOSFET) made from germanium.

To produce Germanium-On-Insulator (GOI or GeOI) substrates, a first technique uses the Smart Cut™ technology, initially developed for producing Silicon-On-Insulator (SOI) substrates, described in particular in the article “200 mm Germanium-On-Insulator (GeOI) structures realized from epitaxial wafers using the Smart Cut™ technology” by C. Deguet et al. (Proceedings ECS 2005, Quebec). This technology is based on transfer, onto a silicon substrate, of a germanium layer deposited on a silicon oxide layer forming an insulating layer. The GOI substrate obtained in this way is of the full wafer type. However, this technology presents a very high cost and nMOSFET transistors are very difficult to achieve.

A second technology is based on the lateral recrystallization principle, in particular described in the article “High-quality single-crystal Ge on insulator by liquid-phase epitaxy on Si substrates” by Y. Liu et al. (Applied Physics Letters, vol. 84, no. 14, Apr. 5, 2004), enabling a localized GOI substrate to be produced. The technique consists in depositing a nitride layer locally on a standard silicon substrate, which layer will form the insulator, and in then depositing a larger layer of germanium thereon, which layer will then be locally in contact with the silicon substrate. Once encapsulated, the stack is heated briefly to the melting temperature of germanium and is then cooled. Solidification of the molten germanium is initiated on the silicon of the substrate (monocrystalline seed), and the front then propagates locally forming a monocrystalline germanium on insulator layer. However, this technique for producing localized GOI substrates is unwieldy, due to interface stability problems, and recrystallization is limited both in extent and in geometry.

A third known fabrication technique uses the germanium condensation technique, also enabling localized GOI substrates to be obtained. This technique is based on the total miscibility of germanium and silicon (same crystalline structure) and on the difference of chemical affinities between germanium and silicon with respect to oxygen, highlighted in particular in the article “A novel Fabrication Technique of Ultrathin and Relaxed SiGe Buffer Layers with High Ge Fraction for Sub-100 nm Strained Silicon-On-Insulator MOSFETs” by T. Tezuka et al. (Jpn. J. AppI. Phys. Vol. 40 (2001) pp. 2866-2874 Part 1, No. 4B, April 2001).

The article “Characterization of 7-nm-thick strained Ge-on-insulator layer fabricated by Ge-condensation technique” by S. Nakaharai et al. (Applied Physics Letters, vol. 83, no. 17, Oct. 27, 2003) in particular describes the fabrication principle of a substrate by germanium condensation.

As represented schematically in FIGS. 1 and 2, fabrication of a substrate 1 comprising a silicon and germanium compound, of the Si_{1-Xf}Ge_{Xf} type, on insulator, with a final germanium concentration Xf comprised between a first non-zero value and 1 comprises formation of a layer 2 of silicon and germanium alloy of Si_{1-Xi}Ge_{Xi} type, with an initial germanium concentration Xi strictly comprised between 0 and Xf. The Si_{1-Xi}Ge_{Xi} layer 2 is deposited on a SOI substrate 3 comprising a buried silicon oxide SiO₂ layer 4 between two silicon layers 5 and forming an insulator for the SOI substrate 3 (FIG. 1).

The second step then consists in performing thermal oxidation treatment of the silicon of the Si_{1-Xi}Ge_{Xi} layer 2, preferably at high temperature. As silicon has a better chemical affinity to oxygen, the germanium is not oxidized. As represented in FIG. 2, thermal oxidation then results in the silicon of the whole of the stack of the SOI substrate 3 and of the Si_{1-Xi}Ge_{Xi} layer 2 being consumed to form a top layer 6 of SiO₂ located on top of the substrate 1. The silicon layer 5 initially arranged between the Si_{1-Xi}Ge_{Xi} layer 2 and the buried SiO₂ layer 4 has been consumed during thermal oxidation and has moved up into the top layer 6 of SiO₂.

In FIG. 2, as germanium is not soluble in SiO₂, a germanium-enriched layer 7 forming the Si_{1-Xf}Ge_{Xf} compound has been rejected against the buried SiO₂ layer 4 and then presents a smaller final thickness Ef than the initial thickness Ei of the Si_{1-Xi}Ge_{Xi} layer 2.

As described in the article “Oxidation of Si_{1-X}Ge_{X} alloys at atmospheric and elevated pressure” by D.C. Paine et al. (J. Appl. Phys. 70(9), Nov. 1, 1991), the germanium condensation process can continue until the silicon has been completely consumed, so as to obtain a layer 7 containing germanium only and forming a GOI compound with a final germanium concentration Xf equal to 1. In the case where the silicon is not completely consumed, the layer 7 then forms a SGOI compound with a final germanium concentration Xf strictly comprised between 0 and 1.

However, a major problem of this germanium condensation technique for fabrication of a substrate 1 comprising a Si_{1-Xf}Ge_{Xf} compound is relaxation of the strains in the germanium-enriched final layer 7. When oxidation of the Si_{1-Xi}Ge_{Xi} layer 2 takes place, there is competition between silicon oxidation and germanium diffusion. A strong composition gradient can lead to a strained local state, such that the layer 7 relaxes plastically. This then results in the appearance of criss-cross dislocation lattices in the layer 7, resulting in particular in poor quality of the substrate 1.

Moreover, the article “Relaxed silicon-germanium-on-insulator fabricated by oxygen implantation and oxidation-enhanced annealing” by Zhijun et al. (Semiconductor Science and Technology IOP Publishing UK) describes another method for producing a SGOI substrate comprising a deposition step of a Si_{1-X}Ge_{X} layer on a silicon substrate followed by an ion implantation step and a thermal oxidation step at a temperature of 1000° C. under pure oxygen. The method then comprises a thermal annealing treatment step with argon combined with 1% of oxygen, at high temperature, in the region of 1300° C. However, such a fabrication method on the one hand proves difficult to implement and on the other hand does not enable a good quality substrate 1 to be obtained.

### OBJECT OF THE INVENTION

The object of the invention is to remedy all the above-mentioned shortcomings and to provide a method for producing a substrate comprising a Si_{1-Xf}Ge_{Xf} silicon and germanium compound on insulator, which method is easy to implement and which presents optimal characteristics in terms of germanium concentration.

According to the invention, this object is achieved by the accompanying claims and more particularly by the fact that the first thermal oxidation step comprises at least one thermal treatment step under an inert gas at said predetermined first oxidation temperature.

### BRIEF DESCRIPTION OF THE DRAWINGS

Other advantages and features will become more clearly apparent from the following description of particular embodiments of the invention given as non-restrictive examples only and represented in the accompanying drawings, in which:

FIGS. 1 and 2 schematically represent two successive steps of a substrate fabrication method according to the prior art.

FIG. 3 is a graph representing the temperature versus time for a substrate fabrication method according to the invention.

FIG. 4 is a graph representing the temperature versus time for an alternative embodiment of a substrate fabrication method according to the invention.

FIG. 5 represents a step of another alternative embodiment of a substrate fabrication method according to the invention.

### DESCRIPTION OF PARTICULAR EMBODIMENTS

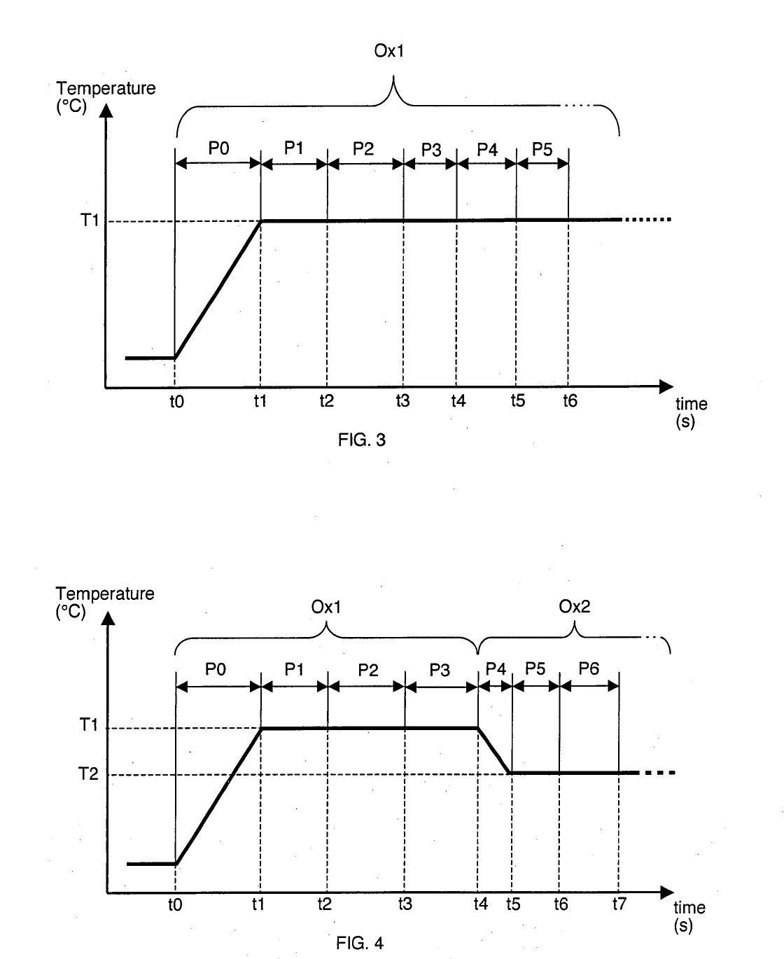

With reference to FIGS. 3 to 5, the fabrication method is designed to produce a silicon and germanium on insulator (SGOI) or a germanium on insulator (GOI) substrate 1, i.e. a substrate comprising a silicon and germanium compound Si_{1-Xf}Ge_{Xf} on insulator. The final germanium concentration Xf is strictly comprised between 0 and 1 for a SGOI substrate, and the final germanium concentration Xf is equal to 1 for a GOI substrate.

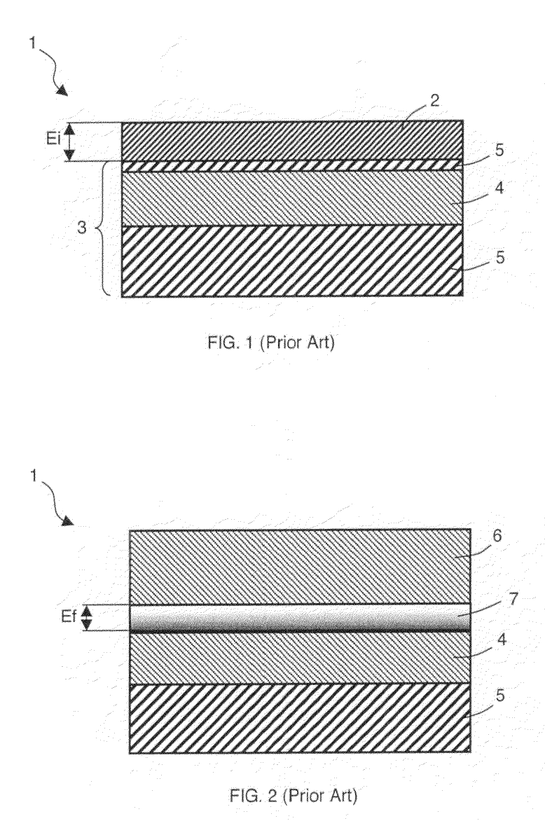

The fabrication method first comprises formation of the substrate on insulator 3 and formation, for example by epitaxy, of the Si_{1-Xi}Ge_{Xi} silicon and germanium alloy layer 2 (FIG. 1). The method then comprises thermal oxidation treatment of the silicon, preferably performed at high temperature and notably consisting in injecting an oxidizing gas into for example a chamber in which the fabrication method of the substrate 1 is performed.

In FIG. 3, a first thermal oxidation step Ox1 of the silicon of the layer 2 comprises a prior temperature increase step P0, between the times t0 and t1, performed under an inert gas, for example nitrogen, helium or argon, under oxygen or under a mixture of oxygen and inert gas. The prior step P0 enables the predetermined first oxidation temperature T1 to be reached, which is preferably lower than the melting temperature of the silicon and germanium alloy of the Si_{1-Xi}Ge_{Xi} layer 2.

The first thermal oxidation step Ox1 then comprises a first thermal oxidation period P1 at the temperature T1, between the times t1 and t2, followed by a first thermal treatment period P2 under an inert gas, between the times t2 and t3, performed at the same temperature, i.e. at the predetermined first oxidation temperature T1. What is meant by inert gas is a pure inert gas, i.e. an inactive gas not reacting with the compounds of the substrate layers, more particularly a gas containing 0% oxygen.

The thermal treatment step under an inert gas, for example nitrogen, consists in stopping injection of oxidizing gas participating in the oxidation step, and injecting pure inert gas instead of the oxidizing gas for a predetermined time and at the same temperature as for oxidation. Injecting inert gas at the predetermined temperature T1 during a predefined time in particular enables diffusion and homogenization of the germanium concentration in the forming layer 7 of the substrate 1.

In the particular embodiment of FIG. 3, a second thermal oxidation period P3, between the times t3 and t4, is then performed after the first thermal treatment period P2 under inert gas, at the predetermined first oxidation temperature T1. Then a second thermal treatment period P4 under inert gas is performed, between the times t4 and t5, as described before. A third thermal oxidation period P5 between the times t5 and t6 is then performed at following the second thermal treatment period P4 under inert gas.

The first thermal oxidation step Ox1 with several intercalated thermal treatment periods under pure inert gas thus continues to be performed so long as the required final germanium concentration Xf remains lower than the concentration leading to melting of the silicon and germanium alloy at the predetermined first oxidation temperature T1.

In a general manner, the initial thickness Ei of the Si_{1-Xi}Ge_{Xi} layer 2 is chosen according to the final thickness Ef required for the Si_{1-Xf}Ge_{Xf} layer 7. The larger the initial thickness Ei, the larger the final thickness Ef will be, the initial thickness Ei of the Si_{1-Xi}Ge_{Xi} layer 2 always having to be smaller than the critical plastic relaxation thickness. Moreover, the final thickness Ef required for the layer Si_{1-Xf}Ge_{Xf} 7 also depends on the enrichment rate, the final concentration Xf being reached more quickly if the initial concentration Xi is high.

For example purposes, the first predetermined oxidation temperature T1 is about 900° C. to 1200° C. and is preferably comprised between 1025° C. and 1075° C. The initial thickness Ei of the Si_{1-Xi}Ge_{Xi}layer 2 is about 100 nm, about 50 nm or about 30 nm and the initial germanium concentration Xi of the Si_{1-Xi}Ge_{Xi} layer 2 is respectively about 10%, about 20% or about 30%.

In a particular embodiment, starting off from an initial Si_{1-Xi}Ge_{Xi} layer 2 with an initial thickness Ei of about 100 nm, with an initial germanium concentration Xi of about 10%, a temperature T1 of about 1050° C. and to obtain a required final germanium concentration Xf of the Si_{1-Xf}Ge_{Xf} layer 7 of about 55% with a final thickness Ef of about 18 nm, the first thermal oxidation step Ox1 comprises thermal oxidation periods of about 15 min, 87 min and 86 min, i.e. a total duration of 188 min, with three intercalated thermal treatment steps under pure inert gas of about 120 min each.

The fabrication method according to the invention, with the first thermal oxidation step Ox1 broken up by thermal treatment periods under an inert gas notably enables a germanium-enriched layer 7 with a smaller final thickness Ef than the initial thickness Ei of the layer 2 to be obtained and enables plastic relaxation of the strains linked to the concentration gradient in the layer 7 formed in this way to be prevented during enrichment. This results in a substrate 1 with optimal qualities as far as the germanium concentration homogenization is concerned.

In an alternative embodiment, not represented, a single thermal treatment period under inert gas can be performed during the first thermal oxidation step Ox1. The thermal treatment period under pure inert gas then presents a sufficient duration enabling the silicon of the Si_{1-Xi}Ge_{Xi} layer 2 to be completely consumed, the required final germanium concentration Xf to be reached and the composition of the Si_{1-Xf}Ge_{Xf} layer 7 formed in this way to be homogenized (FIG. 2).

In another alternative embodiment, a thermal treatment period under pure inert gas can be performed just after the prior temperature increase period P0 of the first thermal oxidation step Ox1. Alternation between the thermal treatment periods under inert gas and the thermal oxidation periods then takes place as before, at the predetermined oxidation temperature T1. In this case, the periods P1, P3 and P5 are thermal treatment periods under inert gas and the periods P2, P4 are thermal oxidation periods. In the case where a single thermal treatment period under pure inert gas is required, the first treatment period following the temperature increase is a thermal treatment period under inert gas and the first thermal oxidation step Ox1 continues, without being interrupted by other thermal treatment steps under inert gas.

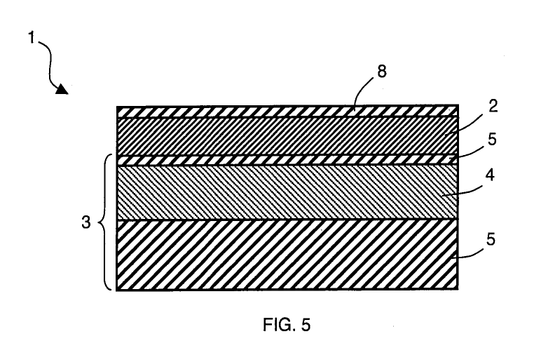

In the alternative embodiment represented in FIG. 4, the thermal oxidation treatment comprises a second thermal oxidation step Ox2 performed at a predetermined second oxidation temperature T2, just after the first thermal oxidation step Ox1. The predetermined second oxidation temperature T2 is lower than the melting temperature of the Si_{1-Xi}Ge_{Xi} alloy and, for example, lower than the predetermined first oxidation temperature T1.

The thermal oxidation treatment therefore comprises a first thermal oxidation step Ox1, for example with the prior temperature increase step P0, between the times t0 and t1, and thermal oxidation periods P1, P3, respectively between the times t1 and t2 and the times t3 and t4, with a thermal treatment period P2 under inert gas intercalated, between the times t2 and t3.

The thermal oxidation treatment therefore comprises a second thermal oxidation step Ox2 comprising an intermediate period P4, for example a temperature decrease period, between the times t4 and t5, until the predetermined second oxidation temperature T2 is reached. The second thermal oxidation step Ox2 then comprises for example a first thermal oxidation period P5, between the times t5 and t6, followed by a thermal treatment period P6 under pure inert gas, between the times t6 and t7.

The second thermal oxidation step Ox2 thus continues its course, with thermal oxidation periods with intercalated thermal treatment periods under inert gas, so long as the required final germanium concentration Xf in the Si_{1-Xf}Ge_{Xf} layer 7 has not be reached.

For example purposes, considering the same couples of values for the initial thickness Ei and the initial concentration Xi as described for FIG. 3, and to obtain a good trade-off between the silicon oxidation rate and the germanium diffusion rate, the predetermined first oxidation temperature T1 is about 1050° C. and the predetermined second oxidation temperature T2 is about 900° C. Thus at 1050° C., the maximum germanium concentration that can be obtained is 65%, to prevent melting of the alloy. To pursue the germanium condensation process, the oxidation temperature then has to be reduced for example to the value T2 of about 900° C., which enables a layer 7 of pure germanium to be obtained, the second oxidation temperature T2 remaining lower than the melting temperature of pure germanium.

In another alternative embodiment, not represented, the thermal oxidation treatment can comprise several other thermal oxidation steps, after the second thermal oxidation step Ox2, each having one or more intercalated thermal treatment steps under pure inert gas. The different additional thermal oxidation steps are then preferably performed at different predetermined oxidation temperatures from the predetermined first T1 and second T2 oxidation temperatures, and preferably with decreasing values. This results in particular in production of a substrate 1 with a Si_{1-Xf}Ge_{Xf} layer 7 presenting optimal characteristics in terms of germanium concentration homogenization.

In another alternative embodiment, the method for producing the substrate 1 can comprise a low-temperature thermal oxidation treatment enabling germanium consumption during the different steps of the germanium condensation process to be prevented. For example, the low-temperature thermal oxidation treatment is performed at a temperature comprised for example between 700° C. and 900° C., and preferably at the beginning of the germanium condensation process.

Furthermore, the low-temperature oxidation step can be performed whatever the number of thermal oxidation steps (FIG. 4) and whatever the number of treatment steps under inert gas (FIGS. 3 and 4).

In FIG. 5, the alternative embodiment of the method for producing the substrate 1 differs from the previously described fabrication methods by deposition of an additional layer 8 of silicon, formed on the Si_{1-Xi}Ge_{Xi} layer 2, before the thermal oxidation treatment to form the Si_{1-Xf}Ge_{Xf} layer 7. The additional layer 8 has a thickness for example from about a few angstroms to a few nanometers and in particular enables a thin layer of SiO₂ to be formed on the top of the substrate 1, preventing consumption of germanium during the first thermal oxidation periods.

Whatever the embodiment of the method for producing the substrate 1 described above, such a method in particular enables a GOI substrate or a SGOI substrate to be fabricated presenting optimal characteristics in terms of germanium concentration, in order to avoid any problems due to relaxation of strains within the layer 7 formed by germanium condensation. Furthermore, such a fabrication method can be implemented whatever the required thickness of the substrate 1 and of the Si_{1-Xi}Ge_{Xi} layer 2 and the Si_{1-Xf}Ge_{Xf} layer 7.

The invention is not limited to the different embodiments described above. The values of the germanium concentrations, of the treatment times and of the thicknesses of the layers are not restrictive and depend on the initial and the required final characteristics of the substrate 1. It is possible to achieve a calibration curve enabling the different values of the treatment time and of the required final germanium concentration to be quickly defined, in particular as a function of the predetermined oxidation temperatures.

For the thermal treatment steps under pure inert gas, nitrogen can be replaced by any pure inert gas, for example by argon, helium, hydrogen or a mixture of hydrogen and nitrogen.

In FIG. 4, the predetermined second oxidation temperature T2 can be higher than the predetermined first oxidation temperature T1, so long as it remains lower than the melting temperature of the Si_{1-Xi}Ge_{Xi} alloy of the layer 2. The first thermal oxidation step Ox1 can comprise additional thermal oxidation periods (not represented), with intercalated additional thermal treatment periods under inert gas (not represented).

Furthermore, in the particular embodiment of FIG. 4, the period P5 of the second thermal oxidation step Ox2 can be a thermal treatment period under inert gas and the period P6 can be a thermal oxidation period. Moreover, a thermal treatment step under inert gas or several thermal treatment steps under inert gas can be intercalated in the second thermal oxidation step Ox2.

1. Method for producing a substrate comprising a silicon and germanium compound of Si_{1-Xf}Ge_{Xf} type on insulator, with Xf comprised between a first value that is not zero and 1, comprising at least:
formation of a layer of silicon and germanium alloy of Si_{1-Xi}Ge_{Xi} type, with Xi strictly comprised between 0 and Xf, on a silicon on insulator substrate,
a first thermal oxidation step of the silicon of said layer at a predetermined first oxidation temperature to obtain said compound of Si_{1-Xf}Ge_{Xf} type by condensation of the germanium, wherein the first thermal oxidation step comprises at least one thermal treatment step under an inert gas at said predetermined first oxidation temperature.

2. Method according to claim 1, wherein the formation step of a layer of silicon and germanium alloy of Si_{1-Xi}Ge_{Xi} type is followed by a formation step of an additional silicon layer.

3. Method according to claim 1, wherein the first thermal oxidation step comprises a prior temperature increase step under an inert or oxidizing atmosphere until said predetermined first oxidation temperature is reached.

4. Method according to claim 1, wherein the first thermal oxidation step comprises a plurality of thermal treatment steps under an inert gas.

5. Method according to claim 1, wherein the predetermined first oxidation temperature is lower than the melting temperature of the Si_{1-Xi}Ge_{Xi} silicon and germanium alloy.

6. Method according to claim 1, comprising at least a second thermal oxidation step performed at a predetermined second oxidation temperature, different from the predetermined first oxidation temperature.

7. Method according to claim 6, wherein the second thermal oxidation step comprises at least one thermal treatment step under an inert gas, at said predetermined second oxidation temperature.

8. Method according to claim 6, wherein the predetermined second oxidation temperature is lower than the melting temperature of the Si_{1-Xi}Ge_{Xi} silicon and germanium alloy.

9. Method according to claim 6, wherein the predetermined first oxidation temperature is about 1025° C. to 1075° C. and the predetermined second oxidation temperature is about 900° C.

10. Method according to claim 1, comprising a low-temperature oxidation step.

11. Method according to claim 1, wherein the final thickness of the Si_{1-Xf}Ge_{Xf} silicon and germanium alloy layer obtained by condensation of the germanium, is smaller than the initial thickness of the Si_{1-Xi}Ge_{Xi} silicon and germanium alloy layer deposited on the substrate on insulator.

12. Method according to claim 11, wherein, to obtain a final germanium concentration of about 55%, the initial thickness is about 100 nm, 50 nm or 30 nm and the initial concentration is respectively about 10%, 20% or 30%.

13. Method according to claim 12, wherein, with an initial thickness of about 100 nm and an initial concentration of about 10%, to obtain a final concentration of about 55%, the first thermal oxidation step has a total duration of about 188 min, with three intercalated thermal treatment periods under an inert gas of about 120 min each.

14. Method according to claim 1, wherein the inert gas is chosen from nitrogen, argon, helium, hydrogen or a mixture of hydrogen and nitrogen.
